(19) United States
(12) Patent Application Publication
(10) Pub. No.: US 2018/0138300 A1
(43) Pub. Date: May 17, 2018

(54) SEMICONDUCTOR DEVICE AND METHOD OF MANUFACTURING THE SAME

(71) Applicant: SANKEN ELECTRIC CO., LTD., Niiza-shi (JP)

(72) Inventors: Ryohei BABA, Niiza-shi (JP); Tomonori HOTATE, Niiza-shi (JP); Satoru WASHIYA, Niiza-shi (JP); Hiroshi SHIKAUCHI, Niiza-shi (JP); Youhei OHNO, Niiza-shi (JP)

(21) Appl. No.: 15/354,993

(22) Filed: Nov. 17, 2016

(51) Int. Cl. H01L 29/739; H01L 29/66; H01L 29/10; H01L 29/36; H01L 29/06; H01L 21/288

(52) U.S. Cl. CPC H01L 29/7397; H01L 29/66348; H01L 21/288; H01L 29/36; H01L 29/0649; H01L 29/1095

(57) ABSTRACT

A semiconductor device includes: a semiconductor substrate including: a drift region that has a first conductivity type; a body region that has a second conductivity type and is formed on the drift region; and an impurity region that has the first conductivity type and is formed in a surface of the body region; a trench, which reaches the drift region; an electric-field relaxation layer, which is formed on at least a portion of a bottom surface out of inner walls of the trench and is electrically connected to the impurity region; a control electrode, which is formed in the trench; an insulating film, which is formed between the control electrode and both the inner walls of the trench and the electric-field relaxation layer; and an electrode, which is connected to the impurity region.

### TECHNICAL FIELD

This disclosure relates to a semiconductor device and a method of manufacturing the same.

### BACKGROUND

There is a semiconductor device such as a power metal-oxide-semiconductor field-effect transistor (MOSFET) or an insulated gate bipolar transistor (IGBT).

In order to reduce a size or a resistance, such a power MOSFET or IGBT employs a trench gate structure in which a gate electrode is buried in a trench formed in a semiconductor substrate.

A transistor having a trench gate structure is disclosed in US 2011/254010. In the transistor, a high-concentration polysilicon layer having a conductivity type opposite to that of a drift region is formed below a gate electrode, and a high switching speed is achieved by the polysilicon layer of a low resistance.

### SUMMARY

In the transistor disclosed in US 2011/254010, after a polysilicon film is generally formed by a thermal CVD (chemical vapor deposition) method, ions such as boron are implanted into the polysilicon film, and thus the polysilicon layer of the low resistance is formed below the gate electrode.

In this way, when a heating process is applied during the formation of the polysilicon layer, the design in consideration of thermal history will be required. In addition, an ion implantation process is required to form the p-type polysilicon film. As a result, manufacturing costs of the transistor increase.

In a case where the high-concentration polysilicon layer is formed below the gate electrode, since the drift region and the high-concentration polysilicon layer form schottky junction, a leak current may increase. In order to reduce the leak current, US 2011/254010 discloses that an impurity region having the conductivity type as the same as the polysilicon layer is formed under the polysilicon layer. In such a configuration, however, manufacturing costs further increase.

This disclosure is to provide a semiconductor device capable of performing high-speed switching and having low manufacturing costs and a method of manufacturing the same.

A semiconductor device of this disclosure includes: a semiconductor substrate, which includes: a drift region that has a first conductivity type; a body region that has a second conductivity type and is formed on the drift region, the second conductivity type being opposite to the first conductivity type; and an impurity region that has the first conductivity type and is formed in a surface of the body region; a trench, which is formed on a front surface of the semiconductor substrate and reaches the drift region; an electric-field relaxation layer, which is formed on at least a portion of a bottom surface out of inner walls of the trench and is electrically connected to the impurity region, the electric-field relaxation layer being made of a metal oxide semiconductor having the second conductivity type; a control electrode, which is formed in the trench; an insulating film, which is formed between the control electrode and both the inner walls of the trench and the electric-field relaxation layer; and an electrode, which is connected to the impurity region.

A method of manufacturing a semiconductor device having a trench formed in a semiconductor substrate and a control electrode formed in the trench, the method includes: forming a semiconductor substrate that includes a drift region that has a first conductivity type; a body region that has a second conductivity type and is formed on the drift region, the second conductivity type being opposite to the first conductivity type; and an impurity region that has the first conductivity type and is formed in a surface of the body region; forming the trench on a front surface of the semiconductor substrate formed in the process of forming the semiconductor substrate to reach the drift region; forming an electric-field relaxation layer on at least a portion of a bottom surface out of inner walls of the trench, the electric-field relaxation layer being made of a metal oxide semiconductor having the second conductivity type;

forming an insulating film on the inner walls of the trench and a surface of the electric-field relaxation layer; and forming a control electrode in the trench, in which the insulating film has been formed.

According to this disclosure, it is possible to provide a semiconductor device capable of performing high-speed switching and having low manufacturing costs and a method of manufacturing the same.

### BRIEF DESCRIPTION OF THE DRAWINGS

The foregoing and additional features and characteristics of this disclosure will become more apparent from the following detailed descriptions considered with the reference to the accompanying drawings, wherein:

FIG. 1 is a schematic cross-sectional view illustrating a schematic configuration of a MOSFET 100 of a semiconductor device according to an embodiment of this disclosure;

FIG. 2A is a schematic cross-sectional view illustrating a manufacturing process of the MOSFET 100 illustrated in FIG. 1;

FIG. 2B is a schematic cross-sectional view illustrating a manufacturing process of the MOSFET 100 illustrated in FIG. 1;

FIG. 2C is a schematic cross-sectional view illustrating a manufacturing process of the MOSFET 100 illustrated in FIG. 1;

FIG. 2D is a schematic cross-sectional view illustrating a manufacturing process of the MOSFET 100 illustrated in FIG. 1;

FIG. 2E is a schematic cross-sectional view illustrating a manufacturing process of the MOSFET 100 illustrated in FIG. 1;

FIG. 3 is a schematic cross-sectional view illustrating a schematic configuration of a MOSFET 200 according to a modified example of the MOSFET 100 illustrated in FIG. 1; and

FIG. 4 is a schematic cross-sectional view illustrating a schematic configuration of a MOSFET 300 according to a modified example of the MOSFET 100 illustrated in FIG. 1.

### DETAILED DESCRIPTION

Embodiments of this disclosure will be described below with reference to the accompanying drawings.

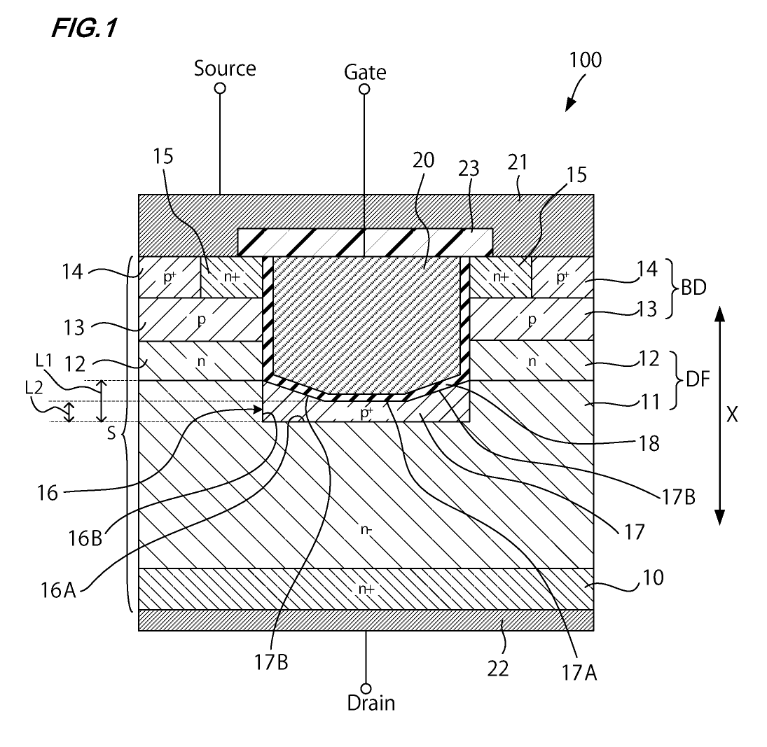

FIG. 1 is a schematic cross-sectional view illustrating a schematic configuration of a MOSFET 100 of a semiconductor device according to an embodiment of this disclosure.

The MOSFET 100 includes a semiconductor substrate S made of a semiconductor such as silicon carbide (SiC).

The semiconductor substrate S includes a front surface serving as an upper surface in FIG. 1 and a back surface serving as a lower surface in FIG. 1. In the following description, out of a thickness direction X being an aligned direction of the back surface and the front surface of the semiconductor substrate S, a direction toward the front surface from the back surface is defined as an upward direction, and a direction toward the back surface from the front surface is defined as a downward direction.

The semiconductor substrate S of the MOSFET 100 is configured with an n-type substrate 10 made of a semiconductor such as silicon or silicon carbide (SiC), an n-type drift region DF that is formed on the substrate 10 and has a lower impurity concentration than the substrate 10, a p-type body region BD that is formed on the drift region DF, and a pair of n-type impurity regions 15 that is formed toward the inside from the surface of the body region BD and has a higher impurity concentration than the drift region DF.

The impurity region 15 constitutes a source region of the MOSFET 100. The substrate 10 constitutes a drain region of the MOSFET 100.

The drift region DF has a laminate structure of an n-type impurity region 11 formed on the substrate 10 and a pair of n-type impurity regions 12 formed on the impurity region 11. The impurity region 12 has a higher impurity concentration than the impurity region 11. The drift region DF may have a configuration (that is, a single-layer structure) in which the impurity region 12 and the impurity region 11 have the same impurity concentration.

The body region BD has a laminate structure of a pair of p-type impurity regions 13 formed on the impurity regions 12 and a pair of p-type impurity regions 14 formed on the impurity regions 13. The impurity region 14 has a higher impurity concentration than the impurity region 13. The body region BD may have a configuration (that is, a single-layer structure) in which the impurity region 13 and the impurity region 14 have the same impurity concentration.

The MOSFET 100 further includes: a drain electrode 22 that is formed on the surface (the back surface of the semiconductor substrate S) of the substrate 10 and is made of a conductive material such as aluminum or titanium; a trench 16 that is formed on the front surface of the semiconductor substrate S and reaches the drift region DF (the impurity region 11 in FIG. 1), an electric-field relaxation layer 17 that is formed on an entire bottom surface 16A out of inner walls (bottom surface 16A and side surface 16B) of the trench 16; a gate electrode 20 that is formed in the trench 16; an insulating film 18 that is formed between the gate electrode 20 and the side surface 16B of the trench 16 and between the gate electrode 20 and the surface of the electric-field relaxation layer 17; and a source electrode 21 formed on the front surface of the semiconductor substrate S through an interlayer insulating film 23 including a BPSG (Boron Phosphorus Silicon Glass), a PSG film, or the like.

The electric-field relaxation layer 17 is configured such that the surface is non-parallel with respect to the front surface of the semiconductor substrate S and a thickness (a distance in the thickness direction X) L1 of a portion coming in contact with the side surface 16B out of the inner walls of the trench 16 becomes larger than a thickness (a distance in the thickness direction X) L2 of a portion formed on the center of the bottom surface 16A of the trench 16.

Specifically, the electric-field relaxation layer 17 is formed in which the thickness (the distance in the thickness direction X) is constant at the central portion of the trench 16 in a direction (a horizontal direction in FIG. 1) perpendicular to the thickness direction X and the thickness gradually increases toward the side surface 16B of the trench 16 from the central portion.

The surface of the electric-field relaxation layer 17 includes a flat face 17A that is formed to be substantially parallel to the front surface of the semiconductor substrate S located at the central portion, and inclined surfaces 17B that are adjacent to and are inclined to the flat face 17A at both sides of the central portion. The inclined face 17B may be a curved surface.

The electric-field relaxation layer 17 is configured with a p-type metal oxide semiconductor having a conductivity type opposite to the conductivity type of the drift region DF, and is electrically connected to the source electrode 21 by wiring (not illustrated). The electric-field relaxation layer 17 has a function to relax an electric field generated in the vicinity of the boundary with the gate electrode 20 in the drift region DF.

As the p-type metal oxide semiconductor, a metal oxide semiconductor such as nickel oxide or zinc oxide, into which lithium ions or oxygen ions is implanted, can be used.

The gate electrode 20 is a control electrode used to control an applied voltage, and is made of a conductive material such as polysilicon. By the control of the voltage to be applied to the gate electrode 20, a channel is formed in the impurity region 13 adjacent to the trench 16, and charges can be transferred to the substrate 10, which is a drain region, from the impurity region 15 through the drift region DF.

A surface of the gate electrode 20 (a lower surface of the gate electrode 20) facing the electric-field relaxation layer 17 is non-parallel to the front surface of the semiconductor substrate S, and is shaped along a surface of the electric-field relaxation layer 17 (the surface of the electric-field relaxation layer 17) facing the gate electrode 20.

That is, the gate electrode 20 is shaped in which the thickness (the distance in the thickness direction X) becomes largest at the central portion of the trench 16 and the thickness becomes gradually smaller toward the side surface 16B from the central portion.

The gate electrode 20 is buried in the semiconductor substrate S in FIG. 1, but the upper surface thereof may protrude above the front surface of the semiconductor substrate S.

The insulating film 18 is configured by, for example, an oxide film made of silicon dioxide or the like, a nitride film made of silicon nitride or the like, or a mixed film of the oxide film and the nitride film.

There is a contact point between the inclined face 17B of the electric-field relaxation layer 17 and the side surface 16B of the trench 16, and the position of the contact point is set lower than the surface of the drift region DF in the thickness direction X such that the lower surface of the gate electrode 20 can be located below the lower surface of the impurity region 13.

The source electrode 21 is made of a conductive material such as aluminum or titanium, which is connected to the impurity region 14 and the impurity region 15.

A method of manufacturing the MOSFET 100 configured as above will be described below.

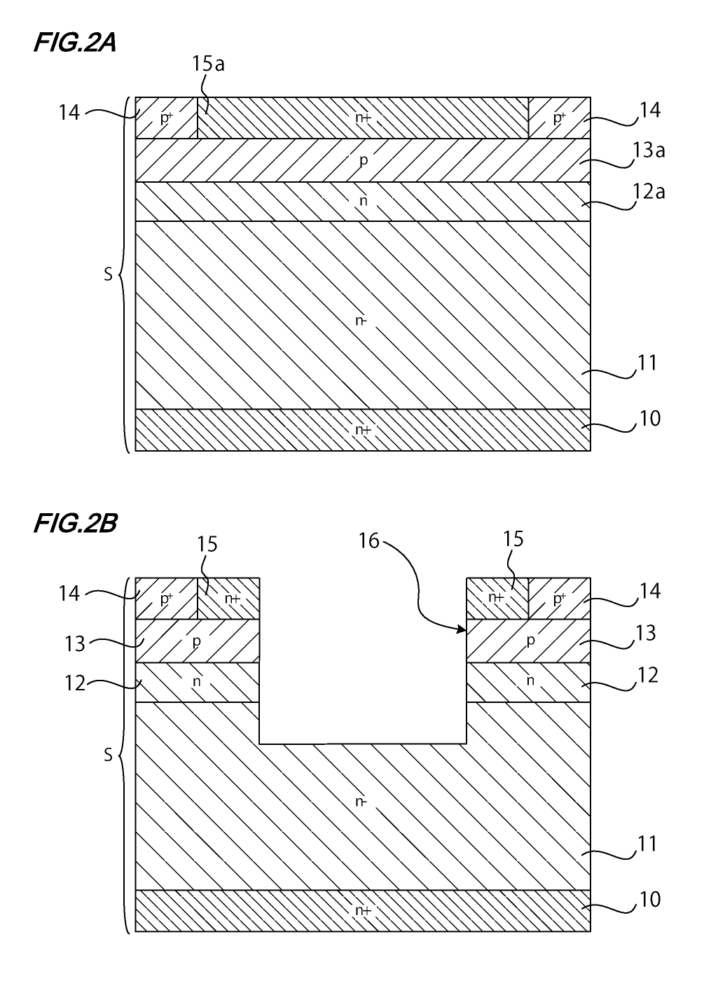

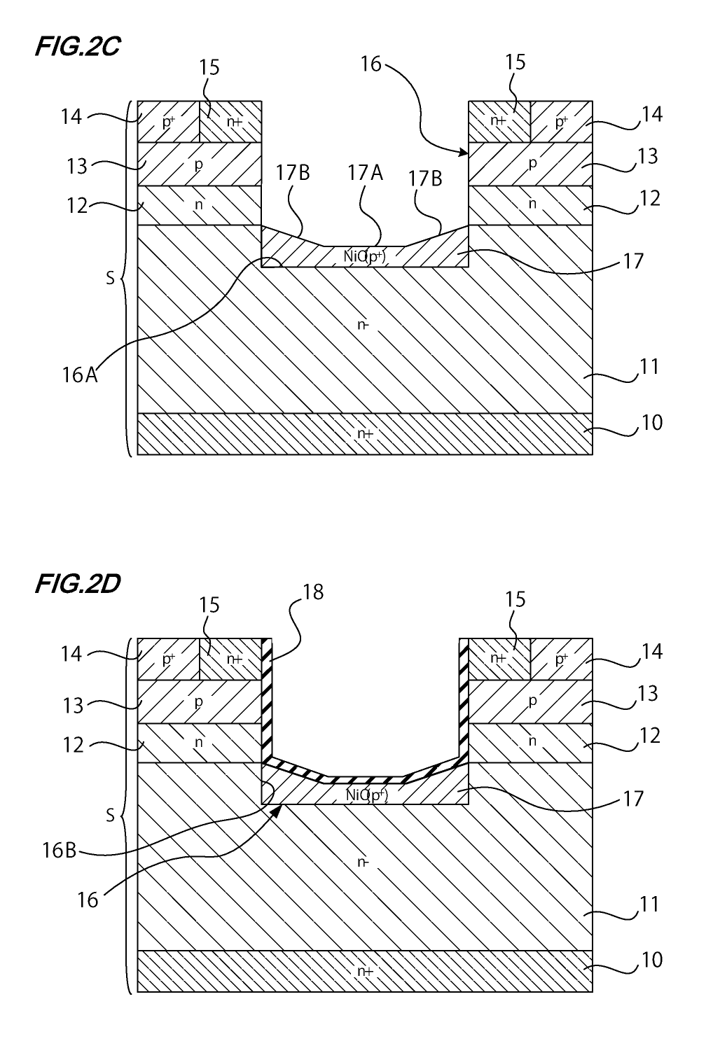

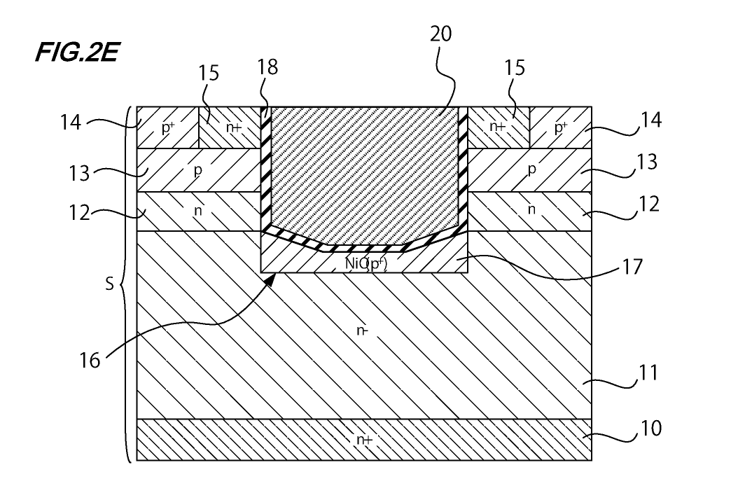

FIGS. 2A to 2E are schematic cross-sectional views illustrating manufacturing processes of the MOSFET 100 illustrated in FIG. 1.

As illustrated in FIG. 2A, the n-type impurity region 11 is formed on the substrate 10 by epitaxial growth, ion implantation, or the like, an n-type impurity region 12a is formed on the impurity region 11 by epitaxial growth, ion implantation, or the like, a p-type impurity region 13a is formed on the impurity region 12a by epitaxial growth, ion implantation, or the like, the p-type impurity regions 14 and an n-type impurity region 15a are formed on the impurity region 13a by epitaxial growth, ion implantation, or the like, and the semiconductor substrate S is formed.

Subsequently, a resist mask pattern is formed on the semiconductor substrate S by, for example, a photolithography method, the semiconductor substrate

S is etched by using the mask pattern, and the trench 16 is formed to reach the impurity region 11 from the front surface of the semiconductor substrate S, as illustrated in FIG. 2B.

The impurity region 12a is divided into two parts by the trench 16, and thus the pair of impurity regions 12 are formed as illustrated in FIG. 1. The impurity region 13a is divided into two parts by the trench 16, and thus the pair of impurity regions 13 are formed as illustrated in FIG. 1. The impurity region 15a is divided into two parts by the trench 16, and thus the pair of impurity regions 15 are formed as illustrated in FIG. 1.

Subsequently, a mask pattern having an opening located only above the trench 16 is formed on the front surface of the semiconductor substrate S by a photolithography method, for example. Then, the p-type metal oxide semiconductor is deposited in the trench 16 by a sputtering method by using the mask pattern, thereby forming the electric-field relaxation layer 17 (FIG. 2C).

By adjustment of various conditions in forming a film of the p-type metal oxide semiconductor by using the sputtering method and the size or the like of the opening in the mask pattern, it is possible to control an inclination angle of the inclined face 17B of the electric-field relaxation layer 17.

Next, as illustrated in FIG. 2D, the insulating film 18 is made of silicon dioxide on the side surfaces 16B of the trench 16 and the surface of the electric-field relaxation layer 17 by a CVD method, for example.

Next, as illustrated in FIG. 2E, a silicon-based conductive material such as polysilicon is deposited in the trench 16, on which the insulating film 18 has been formed, by a plasma CVD method or a sputtering method, and then is subjected to flattening with a CMP (Chemical Mechanical Polishing), for example, thereby forming a gate electrode 20.

Thereafter, an interlayer insulating film including a BPSG film or a PSG film is formed on the front surface of the semiconductor substrate S and the gate electrode 20 by a CVD method, for example, and an opening is formed in the interlayer insulating film. Then, the opening is filled with a meal material such as aluminum or titanium by a sputtering method or a CVD method, thereby forming a source electrode 21. The MOSFET 100 is formed by the above processes.

As described above, according to the MOSFET 100, the electric-field relaxation layer 17 made of the p-type metal oxide semiconductor of the low resistance is formed below the gate electrode 20, and thus it is possible to effectively relax the electric field applied to the insulating film 18 coming in contact with the drift region DF and improve durability of the insulating film 18. Furthermore, since the electric-field relaxation layer 17 is connected to the source electrode 21, and it is possible to extract charges with a high speed and to make a switching speed higher.

According to the MOSFET 100, since the electric-field relaxation layer 17 is made of the p-type metal oxide semiconductor, the electric-field relaxation layer 17 can be formed by the sputtering method. According to the sputtering method, since the semiconductor substrate S is not exposed to a high temperature, it is possible to suppress unnecessary thermal history from being applied. Moreover, since the electric-field relaxation layer 17 can be formed only by deposition of the material with the sputtering method, it is not necessary to perform an ion implantation process. Thus, according to the MOSFET 100, the manufacturing costs can be reduced.

According to the MOSFET 100, the junction between the electric-field relaxation layer 17 and the impurity region 11 forms a schottky junction but forms a pn junction. For this reason, it is possible to reduce a leak current without adding a layer made of a p-type SiC under the electric-field relaxation layer 17 as in the related art, and thus the manufacturing costs can be reduced.

In the MOSFET 100, the thickness of the electric-field relaxation layer 17 gradually increases toward the side surfaces 16B from the central portion of the trench 16, and the lower surface of the gate electrode 20 is shaped along the shape of the surface of the electric-field relaxation layer 17.

Therefore, an angle of an edge of the gate electrode 20 located below the upper surface of the drift region DF can be set to be 90 degrees or more in the cross section of FIG. 1, and the electric field can be prevented from being concentrated in the vicinity of the edge. Accordingly, the durability of the insulating film 18 can be further improved, and the reliability of the device can be improved.

When a ratio (L1/L2) of the thickness L1 to the thickness L2 illustrated in FIG. 1 is larger than 1, it is possible to relax the concentration of the electric field in the vicinity of the edge of the gate electrode 20.

The ratio is set such that the contact point between the inclined face 17B of the electric-field relaxation layer 17 and the side surface 16B of the trench 16 is closer to the front surface of the semiconductor substrate S from the boundary position of the impurity region 11 and the impurity region 12, and thus the effect of the electric field relaxation can be enhanced.

Additionally, as the contact point closes to the the impurity region 13, a gate-drain capacitance can be reduced. Therefore, if the contact point is located at the boundary position of the impurity region 12 and the impurity region 13, the effect of reducing the gate-drain capacitance is maximized, and thus it is possible to improve the high-frequency property.

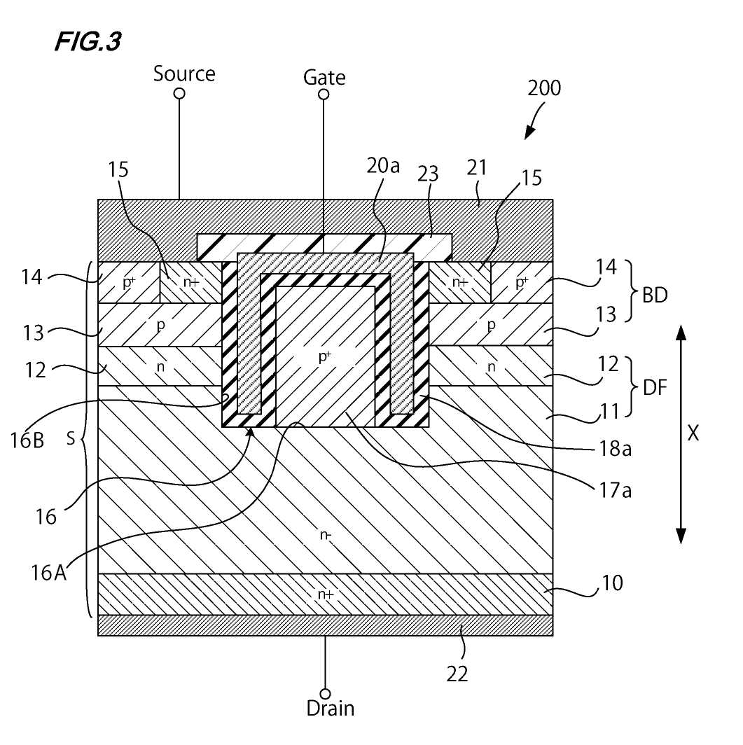

FIG. 3 is a schematic cross-sectional view illustrating a schematic configuration of a MOSFET 200 according to a modified example of the MOSFET 100 illustrated in FIG. 1.

The MOSFET 200 has the same configuration as that of the MOSFET 100 except that the electric-field relaxation layer 17, the insulating film 18, and the gate electrode 20 formed in the trench 16 are changed into an electric-field relaxation layer 17a, an insulating film 18a, and a gate electrode 20a, respectively.

The electric-field relaxation layer 17a has the same material and function as those of the electric-field relaxation layer 17 and is formed on a portion (central portion) of a bottom surface 16A of the trench 16. The electric-field relaxation layer 17a is electrically connected to a source electrode 21.

The gate electrode 20a has the same material and function as those of the gate electrode 20, and has substantially an U-shape to hold the electric-field relaxation layer 17a.

The insulating film 18a has the same material and function as those of the insulating film 18, and is formed between the surface of the electric-field relaxation layer 17a and inner walls of the trench 16 and between the surface of the electric-field relaxation layer 17a and the gate electrode 20a.

According to the MOSFET 200, an electric field generated in the vicinity of the gate electrode 20a can be relaxed by the electric-field relaxation layer 17a, and thus durability of the insulating film 18a can be improved.

In addition, since the electric-field relaxation layer 17a is connected to the source electrode 21, it is possible to make a switching speed higher. Moreover, since the electric-field relaxation layer 17a is made of a p-type metal oxide semiconductor, it is possible to reduce manufacturing costs as in the MOSFET 100.

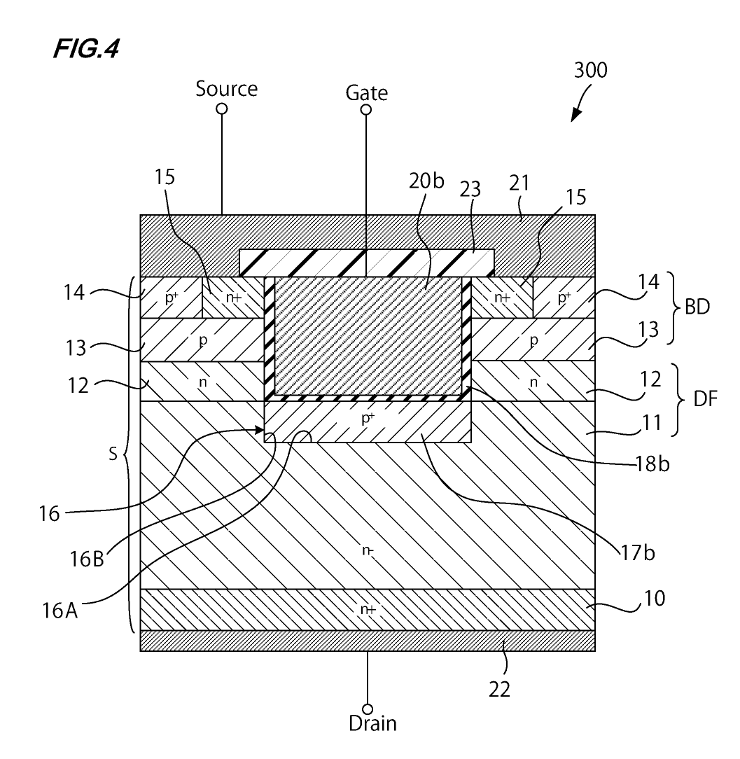

FIG. 4 is a schematic cross-sectional view illustrating a schematic configuration of a MOSFET 300 according to a modified example of the MOSFET 100 illustrated in FIG. 1.

The MOSFET 300 has the same configuration as that of the MOSFET 100 except that the electric-field relaxation layer 17, the insulating film 18, and the gate electrode 20 formed in the trench 16 are changed into an electric-field relaxation layer 17b, an insulating film 18b, and a gate electrode 20b, respectively.

The electric-field relaxation layer 17b has the same material and function as those of the electric-field relaxation layer 17, and is formed on the entire bottom surface 16A of the trench 16. The shape of the electric-field relaxation layer 17b is different from that of the electric-field relaxation layer 17 in that the thickness is constant. The electric-field relaxation layer 17b is electrically connected to a source electrode 21.

The gate electrode 20b has the same material and function as those of the gate electrode 20, and is different from the gate electrode 20 in that a cross section thereof has a rectangular shape.

The insulating film 18b has the same material and function as those of the insulating film 18, and is formed between the surface of the electric-field relaxation layer 17b and side surfaces 16B of the trench 16 and between surface of the electric-field relaxation layer 17b and the gate electrode 20b.

According to the MOSFET 300, an electric field generated in the vicinity of the gate electrode 20b can be relaxed by the electric-field relaxation layer 17b, and thus durability of the insulating film 18b can be improved.

In addition, since the electric-field relaxation layer 17b is connected to the source electrode 21, it is possible to make a switching speed higher. Moreover, since the electric-field relaxation layer 17b is made of a p-type metal oxide semiconductor, it is possible to reduce manufacturing costs as in the MOSFET 100.

As a semiconductor device, the MOSFET is exemplified in the above description. However, even in the case of the IGBT, the similar effects can be obtained with the configuration inside the trench 16 described in each of the MOSFETs 100 to 300.

In addition, even when each of the MOSFETs 100 to 300 is configured such that the p-type and the n-type of the regions, the substrate 10, and the electric-field relaxation layer in the semiconductor substrate S are reversed, the similar effects can be obtained. The electric-field relaxation layer can be made of an n-type metal oxide semiconductor such as zinc oxide (ZnO), tin oxide (SnO), titanium oxide (TiO2).

What is claimed is:

1. A semiconductor device comprising:
a semiconductor substrate, which includes:
a drift region that has a first conductivity type;
a body region that has a second conductivity type and is formed on the drift region, the second conductivity type being opposite to the first conductivity type; and
an impurity region that has the first conductivity type and is formed in a surface of the body region;
a trench, which is formed on a front surface of the semiconductor substrate and reaches the drift region;
an electric-field relaxation layer, which is formed on at least a portion of a bottom surface out of inner walls of the trench and is electrically connected to the impurity region, the electric-field relaxation layer being made of a metal oxide semiconductor having the second conductivity type;
a control electrode, which is formed in the trench;
an insulating film, which is formed between the control electrode and both the inner walls of the trench and the electric-field relaxation layer; and
an electrode, which is connected to the impurity region.

2. The semiconductor device according to claim 1,
wherein the electric-field relaxation layer is formed to cover the entire bottom surface out of the inner walls of the trench and is formed such that a thickness of a portion coming in contact with side surfaces out of the inner walls of the trench is larger than a thickness of a portion formed on a center of the bottom surface of the trench, and
wherein a surface of the control electrode facing the electric-field relaxation layer is along a surface of the electric-field relaxation layer facing the control electrode.

3. The semiconductor device according to claim 1,
wherein the electric-field relaxation layer is made of nickel oxide.

4. The semiconductor device according to claim 1,
wherein the electric-field relaxation layer is made of zinc oxide.

5. A method of manufacturing a semiconductor device having a trench formed in a semiconductor substrate and a control electrode formed in the trench, the method comprising:
forming a semiconductor substrate that includes a drift region that has a first conductivity type; a body region that has a second conductivity type and is formed on the drift region, the second conductivity type being opposite to the first conductivity type; and an impurity region that has the first conductivity type and is formed in a surface of the body region;
forming the trench on a front surface of the semiconductor substrate formed in the process of forming the semiconductor substrate to reach the drift region;
forming an electric-field relaxation layer on at least a portion of a bottom surface out of inner walls of the trench, the electric-field relaxation layer being made of a metal oxide semiconductor having the second conductivity type;
forming an insulating film on the inner walls of the trench and a surface of the electric-field relaxation layer; and
forming a control electrode in the trench, in which the insulating film has been formed.

6. The method according to claim 5,
wherein, in the forming the electric-field relaxation layer, the electric-field relaxation layer is formed of the metal oxide semiconductor having the second conductivity type, by using a sputtering method.

7. The method according to claim 6,
wherein, in the forming the electric-field relaxation layer, the electric-field relaxation layer is formed of the metal oxide semiconductor on the entire bottom surface out of the inner walls of the trench and is formed such that a thickness of a portion of the electric-field relaxation layer coming in contact with a side surface out of the inner walls of the trench is larger than a thickness of a portion formed on a center of the bottom surface of the trench.

8. The method according to claim 6,
wherein the metal oxide semiconductor is one of nickel oxide and zinc oxide.
